(19) United States
(12) Patent Application Publication
(10) Pub. No.: US 2017/0212472 A1
(43) Pub. Date: Jul. 27, 2017

(54) SYSTEM AND METHOD FOR HOLOGRAPHY-BASED FABRICATION

(71) Applicant: Wasatch Photonics, Inc., Logan, UT (US)

(72) Inventor: Gerald L. Heidt, Nibley, UT (US)

(21) Appl. No.: 15/482,671

(22) Filed: Apr. 7, 2017

Related U.S. Application Data
(63) Continuation of application No. 15/037,407, filed on May 18, 2016, now abandoned.
(60) Provisional application No. 61/907,964, filed on Nov. 22, 2013.

(51) Int. Cl. G03H 1/20; G03F 7/26; G03H 1/18; G03F 7/20; G03H 1/00; G03H 1/04

(52) U.S. Cl. CPC G03H 1/20; G03H 1/0005; G03H 1/041; G03H 1/182; G03F 7/70408; G03F 7/70283; G03F 7/26; G03F 7/20; G03H 2001/0094; G03H 2223/17; G03H 2001/185

(57) ABSTRACT

A system and method may utilize holography to facilitate fabrication techniques such as 3D printing and lithography. The system may include a light source, a hologram of an original object or lithographic pattern recorded in a holographic medium, and a target such as a reservoir of photosensitive material or a photosensitive material attached to a substrate. Illuminating the hologram with the appropriate light source may cause a holographic image of the original object or lithographic pattern to form on the photosensitive material within the reservoir or on the substrate. Formation of the holographic image may result in the formation of a new object from the photosensitive material, or may facilitate removal or retention of photosensitive material as part of a lithographic process.

### CLAIMS OF PRIORITY

This application is a continuation of U.S. patent application Ser. No. 15/037,407 (“the '407 Application”), filed May 18, 2016. The '407 Application is a national stage entry of PCT/US14166982 (“the '982 Application”), filed Nov. 22, 2014. The '982 Application claims priority to provisional U.S. Patent Application No. 61/907,964, filed Nov. 22, 2013. These applications are incorporated by reference herein in their entirety

### TECHNICAL FIELD

The present invention relates to fabrication of items, and more particularly, to systems and method of using holography to facilitate optical manufacturing processes.

### BACKGROUND

In many manufacturing processes, electromagnetic energy is used to selectively process materials. Electromagnetic energy includes a spectrum of wavelengths including visible light, higher-frequency energy (such as ultraviolet light, X-rays, and Gamma rays), and lower-frequency energy (such as radio waves, microwaves, and infrared radiation). For simplicity, electromagnetic energy of all wavelengths is often referred to as “light,” Materials that undergo a significant change in response to impingement of light are called “photosensitive materials.”

Existing light-based manufacturing processes include 30 printing, photolithography, and a variety of other processes. These processes are limited in many respects. Many such processes are unable to satisfactorily to produce nanostructures, which may be structures that are smaller than 100 nm. There are many reasons for this, including the quality of the reduction optics used to reduce the size of the illuminated image used for fabrication. Even with high-quality reduction optics, diffraction limitations are still present with many manufacturing methods, and limit the amount of image reduction that can be successfully be carried out. Existing interference lithography techniques may be able to create smaller structures than other techniques, but may be limited to production of periodic patterns.

In order to create smaller structures such as MEMS (micro-electromechanical systems) devices and high-density integrated circuits, it would be advantageous to provide fabrication systems or methods that overcome the limitations set forth above.

### SUMMARY

The present invention may remedy the shortcomings of prior art fabrication methods by providing systems and/or methods for holography-based fabrication. Such fabrication may include, but is not limited to, 30 printing and lithography. Such a system may include a coherent light source, a non-coherent narrow line width source, a monochromatic light source, a hologram, a holographic recording medium, and/or a target such as a reservoir of photosensitive material or a photosensitive material attached to a substrate.

A hologram of an original object or a lithographic pattern may be recorded on the holographic recording medium through the use of a variety of techniques including but not limited to transmission holography, reflection holography, and Denisyuk holography. All three methods may involve splitting a beam of coherent light from a coherent light source, such as a laser, into two or more beams. The beams may include an object beam that is used to illuminate the original object or lithographic pattern, and a reference beam that illuminates the holographic recording medium. A portion of the object beam may reflect from the original object or lithographic pattern onto the holographic recording medium. The reflected portion of the object beam may cooperate with the reference beam to define an interference pattern that records a hologram of the original object or lithographic pattern in the holographic recording medium. After processing the holographic recording medium, creation of the hologram may be complete. The hologram may then be used in the described process.

In transmission holography, the reference beam and the reflected portion of the object beam may both impinge against the same side of the holographic recording medium. In reflection holography, the reference beam and the reflected portion of the object beam may impinge against opposite sides of the holographic recording medium. In Denisyuk holography, the holographic recording medium may, itself, be used as a beam splitter that divides the coherent light into the object beam and the reference beam.

Once the hologram has been recorded and processed, it may be considered an “H1 master hologram” that may be used to fabricate objects and/or create one or more derivative holograms. Specifically, a light source, of a desired wavelength, may be directed at the Hi master hologram to form a holographic image of the original object or lithographic pattern. The holographic image may be positioned in a reservoir of photosensitive material, on a photosensitive material attached to a substrate for lithographic processing, or the like. This may result in the formation of a new object from the photosensitive material, or may facilitate removal or retention of photosensitive material as part of a lithographic process.

If desired, the holographic image may be made smaller than the original object or lithographic pattern. This may be done by positioning image reduction optics between the H1 master hologram and the photosensitive material. Additionally or alternatively, a second hologram may be formed in a second holographic recording medium by using a coherent light source to illuminate the H1 master hologram to form the holographic image. Light from the holographic image may be used as the object beam. Light that was split off of the coherent light source may be redirected to the second holographic recording medium as a reference beam. Image reduction optics may be positioned between the H1 master hologram and the second holographic recording medium to cause the second hologram to be smaller than the H1 master hologram. The second holographic recording medium may record a hologram that, after processing, defines an “H2 hologram.” The H2 hologram may be illuminated to form a smaller holographic image on the photosensitive material.

Through the present invention, nanostructures (for example, structures smaller than 100 nm in dimension, although the scope of the present disclosure should not be limited in this regard) may be successfully formed via the application of a hologram to 30 printing and lithographic processing methods. Diffraction limitations of optical systems may be overcome due to the fact that the holographic image may, itself, be generated through diffraction.

### BRIEF DESCRIPTION OF THE DRAWINGS

FIG. 1 is a schematic view of a system for recording a holographic image according to one embodiment of the invention.

FIG. 2 is a flowchart diagram illustrating a method of forming an H1 master hologram according to one embodiment of the invention.

FIG. 3 is a schematic view of a transmission holographic recording system according to one embodiment of the invention.

FIG. 4 is a schematic view of a reflection holographic recording system according to another embodiment of the invention.

FIG. 5 is a schematic view of a Denisyuk holographic recording system according to another embodiment of the invention.

FIG. 6 is a schematic view of a holographic imaging system according to one embodiment of the invention.

FIG. 7 is a flowchart diagram illustrating a method for applying holographic imaging to a fabrication process according to the present invention.

FIG. 8 is a schematic view of a holographic imaging system as applied to 3D printing according to one embodiment of the invention.

FIG. 9 is a schematic view of a holographic imaging system as applied to 3D printing according to another embodiment of the invention.

FIG. 10 is a schematic view of an H2 holographic recording system as applied to 3D printing according to another embodiment of the invention.

FIG. 11 is a schematic view of a holographic imaging system as applied to lithography according to one embodiment of the invention.

FIG. 12 is a schematic view of an H2 holographic recording system as applied to lithography according to another embodiment of the invention.

### DETAILED DESCRIPTION

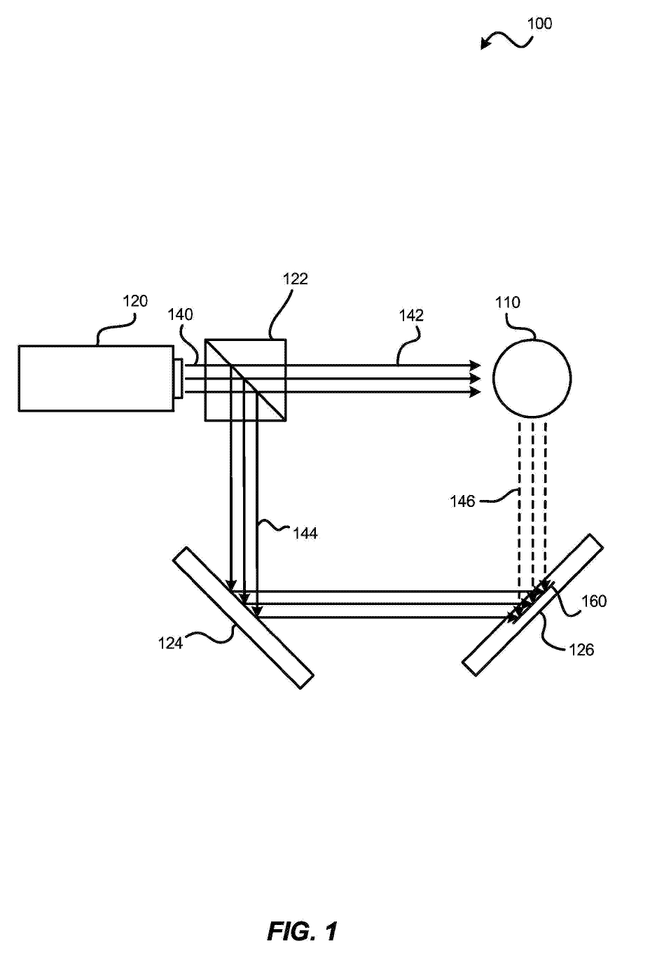

Various embodiments of the invention will now be described in greater detail in connection with FIGS. 1-12. The drawings and associated descriptions are merely exemplary the scope of the invention is defined not by these, but by the appended claims.

Referring to FIG. 1, a schematic diagram illustrates a system 100 for recording a hologram according to one embodiment of the invention. The system 100 may be designed to record a hologram of an item 110, which may be a three-dimensional object, a two-dimensional or three-dimensional pattern, or the like. According to certain examples, the item 110 may be an original object that is to be used as a template for producing new objects via 3D printing. According to other examples, the item 110 may be a lithographic pattern that is to be used as a basis for additive or subtractive lithographic processing. In such instances, the item 110 may be an integrated circuit design, an inverse of an integrated circuit design that defines regions between integrated circuit components, or the like. In other embodiments, the item 110 may be used for processes besides 3D printing and lithography, and may be used in other ways than as a manufacturing template.

The system 100 may have a wide variety of configurations, many of which are known in the holography arts. According to the embodiment shown, the system 100 may include a coherent light source 120, a beam splitter 122, redirection optics 124, and a holographic recording medium 126. Beam expanding optics such as lenses, microscope objectives, and collimating mirrors and optics may be incorporated into system 100 to acquire the needed beam coverage to record the desired hologram.

The coherent light source 120 may be any light source designed to emit coherent light (i.e., light of a substantially uniform wavelength and/or frequency). In this application, “light” is not limited to visible light, but may include electromagnetic radiation of any frequency or wavelength. In certain embodiments, the coherent light source 120 may be a laser or the like. The coherent light source 120 may project a first beam 140 of coherent light toward the beam splitter 122.

The beam splitter 122 may be designed to receive the first beam 140 and divide the first beam 140 into two components: an object beam 142 and a reference beam 144. The beam splitter 122 may have any configuration known in the art. If desired, the beam splitter 122 may have the shape of a rectangular prism, which may include two triangular prisms as shown. A portion of the first beam 140 may pass directly through the beam splitter 122 to define the object beam 142, and the remainder of the first beam 140 may reflect from the interface between the prisms to define the reference beam 144. The object beam 142 and the reference beam 144 are shown displaced by an angle of 90°, but may be displaced by a variety of different angles in different embodiments. The object beam 142 and/or the reference beam 144 may require the use beam expanding optics such as lenses, microscope objectives and collimating mirrors (not shown). These optics may be incorporated into system 100 to acquire the needed beam coverage to record the desired hologram.

The reference beam 144 may project toward the redirection optics 124, which may redirect the reference beam 144 toward a holographic recording medium 126. The holographic recording medium 126 may or may not be applied to a substrate for support. The redirection optics 124 may include various structures that provide the necessary redirection; in certain embodiments, the redirection optics 124 may include one or more mirrors. In addition to or in the alternative to redirection of the reference beam 144, the object beam 142 may be redirected through the use of redirection optics (not shown).

A portion 146 of the object beam 142 may reflect off of the item 110 toward the holographic recording medium 126. The portion 146 may cooperate with the reference beam 144 to define an interference pattern at the holographic recording medium 126. The holographic recording medium 126 may be formed of a material that records this interference pattern to record a hologram 160 of the item 110.

The holographic recording medium 126 may also be termed a holographic recording film. The holographic recording medium 126 may have any of a variety of compositions known in the art, including but not limited to Silver Halide film, Dichromated gelatin, PMMA, Photosensitive glass, Photosensitive plastic or a variety of photopolymers. The selection of the particular type of holographic recording medium 126 to use may be made based on factors such as the size of the item 110, the length of the exposure, the required resolution of the hologram 160, and the like.

The hologram 160 may be a three-dimensional representation of the item 110. The holographic recording medium 126, with the hologram 160 recorded thereon, may be subjected to further processing according to the type of holographic medium used to complete creation of the hologram 160. The hologram 160 may be an H1 master hologram. The H1 master hologram may be used to project a holographic image of the item 110, which may, without the use of additional optics, occur at a location that duplicates the original spacing between the item 110 and the holographic recording medium 126 when the hologram 160 was made.

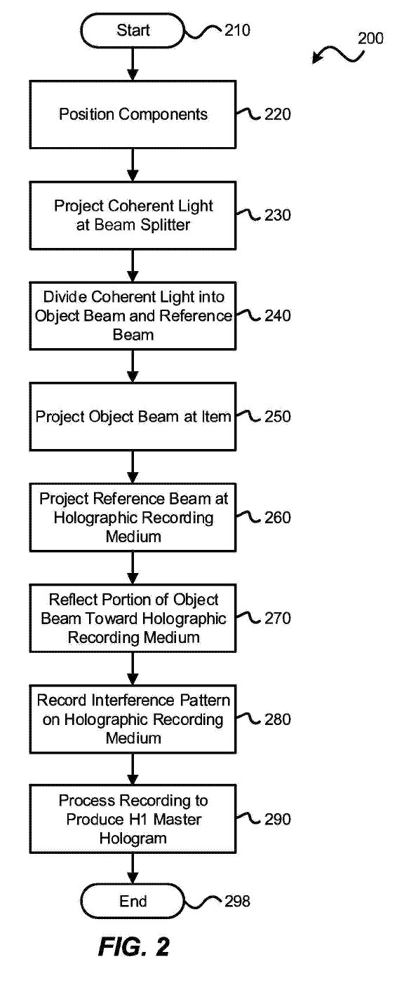

Referring to FIG. 2, a flowchart diagram illustrates a method 200 of forming an Hi master hologram according to one embodiment of the invention. The method 200 may start 210 with a step 220 in which various components are positioned relative to each other in preparation for holographic recording.

The components referenced in the step 220 may include, but are not limited to, the item 110, the coherent light source 120, the beam splitter 122, the redirection optics 124, and the holographic recording medium 126 of FIG. 1. These various components may advantageously be positioned in a stable arrangement such as on an optical table that is isolated from vibration or other motion. They may also be positioned in dark environment so that only the desired coherent light impinges against the holographic recording medium 126.

Once the components have been properly positioned, the method 200 may proceed to a step 230 in which the first beam 140 is projected at the beam splitter 122, for example, by activating the coherent light source 120. Then, in a step 240, the first beam 140 may be divided by the beam splitter 122 into the object beam 142 and the reference beam 144.

Then, in a step 250, the object beam 142 may be projected at the item 110, for example, by the beam splitter 122, with or without redirection by elements such as the redirection optics 124. In a step 260, the reference beam 144 may be projected at the holographic recording medium 126, for example, by the beam splitter 122, with or without redirection by elements such as the redirection optics 124. In a step 270, a portion of the object beam 142 may reflect from the item 110 toward the holographic recording medium 126.

In response to impingement of the reference beam 144 and the object beam portion 146 on the holographic recording medium 126, the hologram 160 may be recorded in a step 280. Then, in a step 290, the holographic recording medium 126 with the hologram 160 may be processed further to complete formation of the hologram 160. This processing may be done according to the type of holographic recording medium used. The hologram 160 may then be an Hi master hologram, which may be used in further holography processes as described above. Then, the method 200 may end 298.

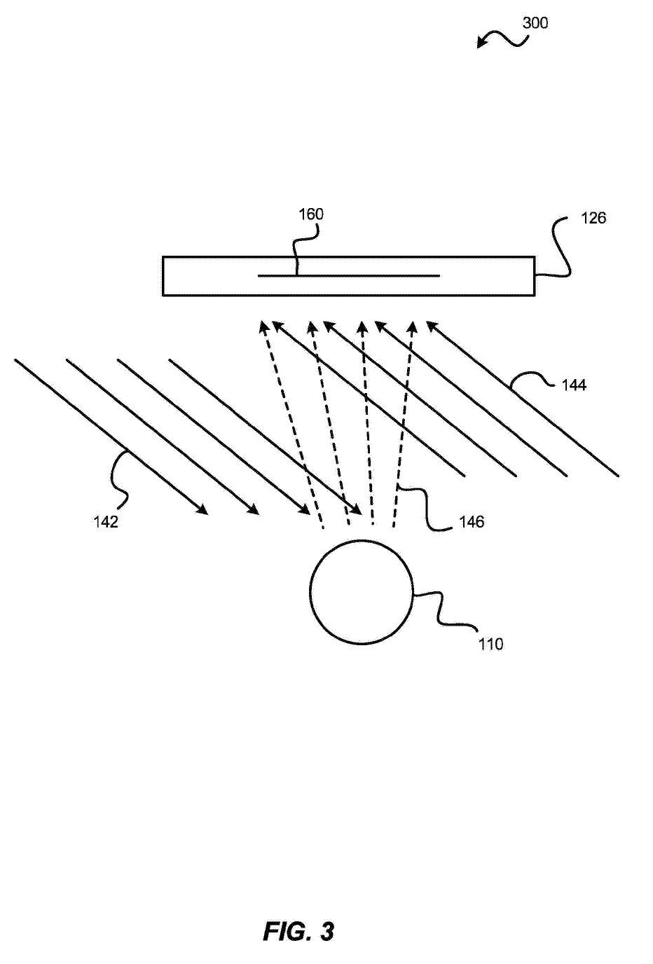

Referring briefly back to the step 220, the various components of the system 100 may be positioned in a variety of ways. These may include transmission holography, reflection holography, and Denisyuk holography, which will be shown and described in connection with FIGS. 3, 4, and 5, as follows. Those of skill in the art will recognize that these arrangements are merely exemplary, and other arrangements of the components of the system 100 may be used.

Referring to FIG. 3, a schematic view illustrates a transmission holographic recording system, or system 300, according to one embodiment of the invention. The system 300 may be a subset of the system 100 that is uniquely configured for transmission hologram recording. As shown, the reference beam 144 and the portion 146 of the object beam 142 may impinge against the same side of the holographic recording medium 126. The reference beam 144 may impinge against the holographic recording medium 126 at a desired angle. As in FIG. 1, the reference beam 144 and the portion 146 of the object beam 142 may cooperate to define an interference pattern, which may cause the hologram 160 to be recorded in the holographic recording medium 126.

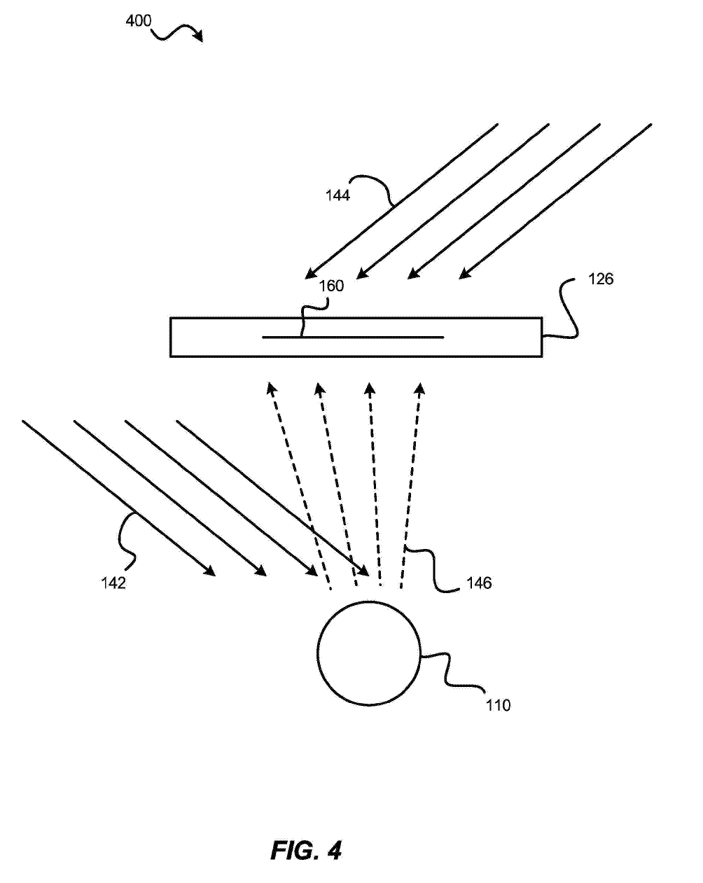

Referring to FIG. 4, a schematic view illustrates a reflection holographic recording system, or system 400, according to another embodiment of the invention. The system 400 may be a subset of the system 100 that is uniquely configured for reflection hologram recording. As shown, the reference beam 144 and the portion 146 of the object beam 142 may impinge against different sides of the holographic recording medium 126. The sides of the holographic recording medium 126 that receive the reference beam 144 and the portion 146 of the object beam 142 may face in directions that are substantially opposite to each other. The reference beam 144 may again impinge against the holographic recording medium 126 at a desired angle. The reference beam 144 and the portion 146 of the object beam 142 may intersect the holographic recording medium 126 and may cooperate to define an interference pattern, which may cause the hologram 160 to be recorded in the holographic recording medium 126.

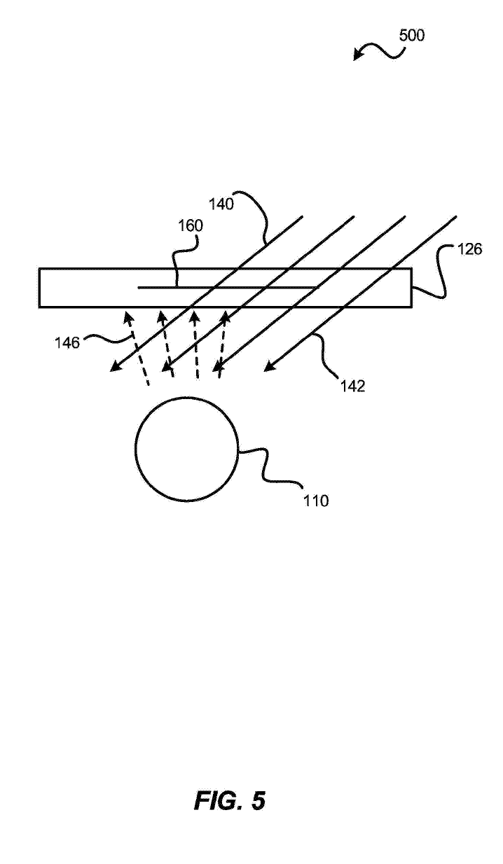

Referring to FIG. 5, a schematic view illustrates a Denisyuk holographic recording system, or system 500, according to another embodiment of the invention. The system 500 may be a subset of the system 100 that is uniquely configured for Denisyuk hologram recording. As shown, the holographic recording medium 126 may act as a beam splitter. Thus, the beam splitter 122 may be omitted from the system 100.

The first beam 140 may impinge directly against the holographic recording medium 126 at a desired angle. The holographic recording medium 126 may receive a portion of the first beam 140 as a reference beam, and may allow transmission of the object beam 142 through the holographic recording medium 126 at the item 110. The portion 146 of the object beam 142 may reflect from the item 110 to the holographic recording medium 126. The reference beam and the portion 146 of the object beam 142 may intersect the holographic recording medium 126 and may cooperate to define an interference pattern, which may cause the hologram 160 to be recorded in the holographic recording medium 126.

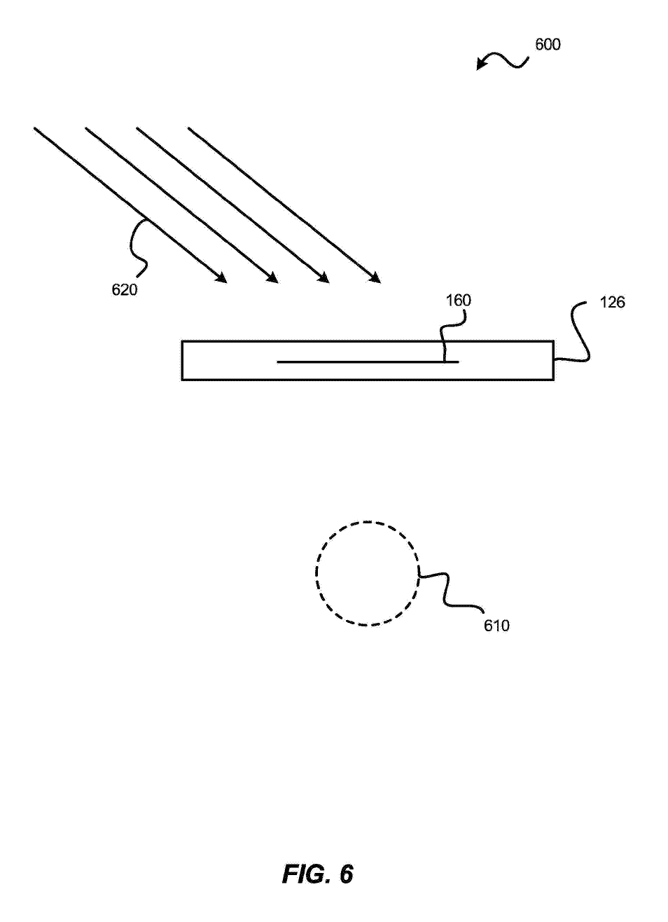

As set forth above, the hologram 160 may be recorded on the holographic recording medium 126 in a wide variety of ways. After the hologram 160 has been recorded and processed, the resulting H1 master hologram may be used to project holographic images. One way in which this may be accomplished will be shown and described in connection with FIG. 6.

Referring to FIG. 6, a schematic view illustrates a transmission holographic imaging system, or system 600, according to one embodiment of the invention. The system 600 may be used to project a holographic image 610 from the H1 master hologram. The holographic image 610 may resemble the item 110, and may thus have a shape similar to a shape of the item 110. The holographic image 610 may not include all of the item 110; for example, only the portions of the item 110 that were illuminated with coherent light that was reflected to the holographic recording medium 126 (i.e., the portion 146 of the object beam 142) may be part of the hologram 160. Thus, the holographic image 610 may include only such portions of the item 110.

The holographic image 610 may be initiated by projecting a beam 620 of coherent light at the H1 master hologram, i.e., at the H1 hologram 160 recorded on the holographic recording medium 126. Notably, the beam 620 need not necessarily be coherent light, since no interference pattern is being created. Thus, the light source used to illuminate the hologram 160 may be, but is not required to be, a coherent light source such as a laser. Rather, the coherent light source may instead be a single or narrow line source or even a monochromatic light source that is not coherent.

The beam 620 may be projected at a selected angle, which may be the Bragg angle applicable to the H1 master hologram. This may be the angle at which the reference beam 144 impinged against the holographic recording medium 126 when the hologram 160 was formed. Additionally, the beam 620 may be composed of coherent light with the same wavelength and/or frequency as that originally used to form the hologram 160. Thus, the coherent light source 120 that was used to form the hologram 160 may advantageously be used to provide the beam 620 of coherent light.

In response to impingement of the beam 620 of coherent light on the hologram 160, the item 110 may be optically imaged, in space, at the same location, relative to the holographic recording medium 126, where it was positioned at the time the hologram 160 was formed. This holographic image may be created by diffraction and formed in open space.

The holographic image 610 may be projected at any of a variety of locations. According to the present invention, it may be beneficial to project the holographic image 610 on a photosensitive material. A “photosensitive material” is a material that undergoes a significant change in response to impingement of light. The change that occurs in response to impingement of light may be any of many possibilities, including but not limited to the material becoming solid, gaseous, transparent, opaque, harder, softer, more susceptible to further processing, or less susceptible to further processing. Additionally or alternatively, an index of refraction of the material may change, either upward or downward in response to impingement of the light.

Notably, the change effected by light may not fully be realized without additional processing such as exposure to other substances that, in combination with impingement of the light, enable the full extent of the desired change. Such additional processing may be carried out before, after, or synchronously with Impingement of the light.

FIG. 6 illustrates transmission holographic imaging, which may be, for example, formed via transmission of the beam 620 through the hologram 160 as shown in FIG. 6. Other holographic imaging methods may be used within the scope of the present invention, including but not limited to reflection holograms. Reflection holograms may be made by projecting a beam, such as the beam 620 of FIG. 6, at the same side of the H1 master hologram that faces the location of the holographic image. The light may impinge on the hologram 160, and may then diffract the light in reflection mode to form a holographic image such as the holographic image 610 of FIG. 6.

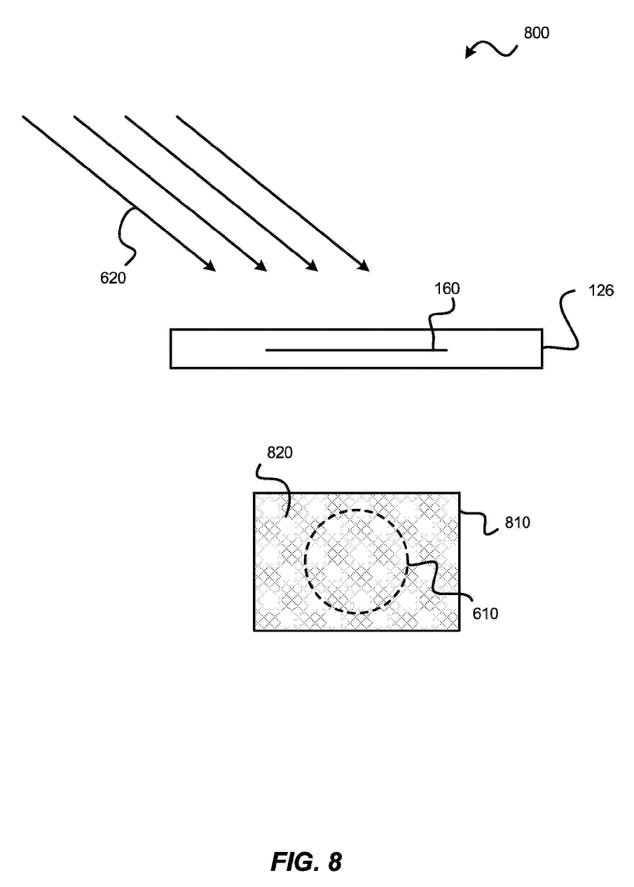

FIGS. 8-12 also generally illustrate transmission holographic imaging, In alternative embodiments, the methods carried out in any of FIGS. 8-12 may instead be accomplished through the use of a reflection hologram or other holographic imaging techniques.

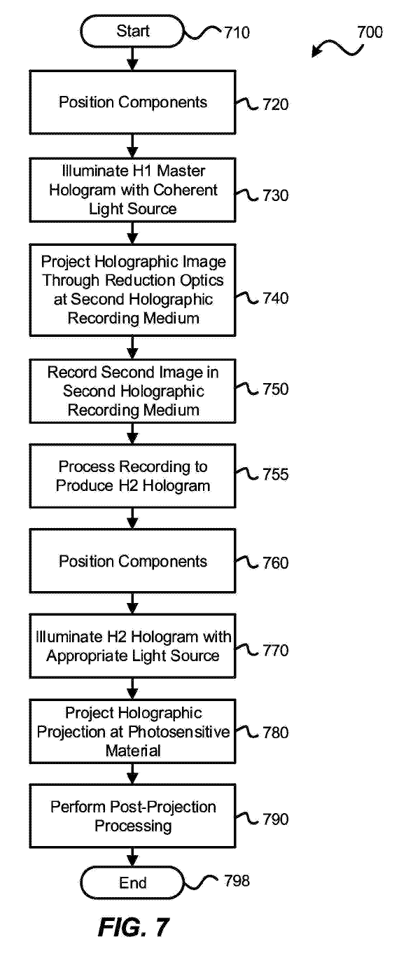

Referring to FIG. 7, a flowchart diagram illustrates a method 700 for applying holographic imaging to a fabrication process according to the present invention. The method 700 is generalized, and thus applies to a wide variety of processes including but not limited to 3D printing and lithography.

The holographic image 610 may be substantially the same size as the item 110. Alternatively, if desired, the holographic image 610 may be smaller than the item 110. In the event that the holographic image 610 is to be used for fabrication of nanostructures (for example, via 3D printing or lithography), the holographic image 610 may advantageously be several orders of magnitude smaller than the item 110.

Thus, the method 700 may include one or more optional image reduction steps; such steps may be omitted if there is no need to reduce the size of the process that occurs relative to that of the original item. Alternatively, in the event that further reduction of the process, relative to the item, is needed, such image reduction steps may be repeated. More specifically, the step 720, the step 730, the step 740, and/or the step 750 may be carried out for image reduction purposes, and may be omitted or repeated as desired. Additionally, the step 780 may also optionally incorporate image reduction.

The method 700 may start 710 with a step 720 in which the components are positioned relative to each other. In this step, the components to be positioned may include the coherent light source 120 (or a different coherent light source), the H1 master hologram, image reduction optics (such as lenses, mirrors, and/or the like), and a second holographic recording medium. These components will be shown and described subsequently in connection with the 3D printing and lithography examples mentioned previously.

As in the step 220, the step 720 may advantageously include secure fixation of the various components relative to each other in an environment that provides isolation from vibration or other outside motion. Additionally, ambient light may be reduced or eliminated. The coherent light source 120 or other coherent light source may be aimed at the Hi master hologram. If desired, redirection optics such as the redirection optics 124 may be positioned to cause coherent light emitted by the coherent light source 120 or other coherent light source to impinge against the H1 master hologram. The image reduction optics may be positioned between the H1 master hologram and the second holographic recording medium.

The method 700 may then proceed to a step 730 in which the H1 master hologram is illuminated with coherent light. This may entail activation of the coherent light source 120 and/or other coherent light source. In the event that a coherent light source other than the coherent light source 120 used to form the hologram 160 is used, it may beneficially emit coherent light with the same wavelength and/or frequency as that emitted by the coherent light source 120. The coherent light may impinge against the H1 master hologram.

In responses to impingement of the coherent light against the H1 master hologram, a step 740 may occur, in which a holographic image is projected from the Hi master hologram through the image reduction optics and at the second holographic recording medium. The image reduction optics may be positioned between the H1 master hologram and the second holographic recording medium. Thus, as the holographic image is projected at the second holographic recording medium, it may be reduced in size so that, at the second holographic recording medium, it is much smaller than the item 110.

In response to projection of the holographic image on the second holographic recording medium, the method 700 may proceed to a step 750 in which the holographic image projected from the H1 master hologram is recorded as a second hologram in the second holographic recording medium. The second hologram may be smaller than the hologram 160 that was originally created from the item 110. Depending on the reduction power of the reduction optics used, the second hologram may be orders of magnitude smaller than the hologram 160. After the appropriate processing of the second hologram and the second holographic recording medium in a step 755, the second hologram may be ready for use as an H2 hologram, as mentioned above.

In the event that the H2 hologram is not sufficiently small, the step 720, the step 730, the step 740, the step 750, and/or the step 755 may be performed again, substituting the new H2 hologram for the H1 master hologram, and substituting a third holographic recording medium for the second holographic recording medium.

More specifically, the H2 hologram, the image reduction optics, the third holographic recording medium, and the coherent light source 120 (or other coherent light source) may all be positioned relative to each other. The image reduction optics used may be the same as those that were used in the original performance of the step 720, the step 730, the step 740, and the step 750. Additionally or alternatively, different image reduction optics may be used, and may be positioned between and/or relative to the H2 hologram and the third holographic recording medium.

Then, the H2 hologram may be illuminated with coherent light. A holographic image may be projected from the H2 hologram, through the image reduction optics, and at the third holographic recording medium. A third hologram may be recorded by the holographic image in the third holographic recording medium. The third hologram may be smaller than the second hologram. After the appropriate processing, the hologram recorded in the third holographic recording medium may become an H3 hologram.

In such a manner, the step 720, the step 730, the step 740, the step 750, and/or the step 755 may be repeated as many times as needed to obtain a holographically recorded image of the desired size. Since each holographic image may be created through diffraction, creation of a reduced holographic image may not be subject to diffraction limitations.

Once a hologram of the desired scale has been created (e.g., in the holographic recording medium 126, the second holographic recording medium, or a subsequently-used holographic recording medium), the method 700 may proceed to a step 760 in which the components are positioned in preparation for the step 770, the step 780, and the step 790. The components positioned in the step 760 may include the hologram created in the most recent iteration of the step 755 (i.e., an H2 hologram or a subsequently-created hologram, hereinafter “final hologram”), a light source of the required wavelength(s) (such as the coherent light source 120), the photosensitive material, and/or image reduction optics.

The coherent light source 120 or a non-coherent light source of the required wavelength may be aimed at the final hologram. If desired, redirection optics such as the redirection optics 124 may be positioned to cause coherent light emitted by the coherent light source 120 or a non-coherent light source of the required wavelength to impinge against the hologram. The image reduction optics may be positioned between the final hologram and the photosensitive material. Again, steps may be taken to ensure the stable placement of the components and/or limit the exposure of the components to ambient light.

Once the components have been properly placed, the method 700 may proceed to a step 770 in which a light source of the required wavelength is used to illuminate the final hologram. This ay be done, for example, by activating the coherent light source 120 or non-coherent light source of the required wavelength. In the event that the light source used in this step is not the same as the coherent light source that which was used to record the final image, it may beneficially emit light with the same wavelength and/or frequency as that emitted by the coherent light source that was used to record the final hologram. The light may then illuminate the hologram created in the most recent iteration of the step 755.

In response to impingement of the light against the hologram on which the final image has been recorded, a step 780 may occur, in which a holographic image is projected from the hologram at the photosensitive material. Optionally, this may entail projection of the holographic image through the image reduction optics.

If used in the step 780, the image reduction optics may be positioned between the final hologram and the photosensitive material. Thus, as the holographic image is projected at the photosensitive material, it may be reduced in size so that, at the photosensitive material, it is smaller than the item 110 and/or the final hologram.

In response to projection of the holographic image on the photosensitive material, the photosensitive material may undergo a significant change. As mentioned previously, this change may take many different forms, and the photosensitive material may require other processing in order for this change to be fully realized. In one example, the photosensitive material may be retained within a reservoir, and may solidify in response to impingement of the holographic image, thus creating a new three-dimensional object. In another example, the photosensitive material may be located on a substrate, and may be made more or less resistant to further etching steps by impingement of the holographic image, thus causing a lithographic pattern to be imaged on the substrate.

Once the holographic image has been projected on the photosensitive material, further processing steps may be performed in a step 790, depending on the type of fabrication process being carried out. For example, if the process is a 3D printing process, projection of the holographic image into a reservoir of photosensitive material may result in the formation of a new object as the photosensitive material that receives the holographic image solidifies in response.

The step 790 may thus include removal of the new object from the reservoir. If needed, surface treatments such as cleaning, deburring, and/or sanding may be carried out. If the new object includes one or more nanostructures, suitable measures may be taken to locate, protect, and store the nanostructures.

If the process is a lithographic process, projection of the holographic image on photosensitive material on a substrate may cause the photosensitive material that receives the holographic image to solidify. Additionally or alternatively, the photosensitive material that receives the holographic image may become more or less susceptible to subtractive (i.e., material removal) processes such as etching. Thus, holographic imaging may be used to determine which portion of the photosensitive material is preferentially etched away, or may be used to protect material from removal via etching. According to some embodiments, the holographic image may be used to form a mask from the photosensitive material. The mask may serve to protect an underlying material from a material removal process such as etching.

According to alternative embodiments, holographic imaging may be used in combination with additive processes such as sputtering or vacuum deposition. The holographic image may be used to form a mask or selective support layer for such additive processing.

Accordingly, the step 790 may include the performance of a wide variety of steps, including but not limited to subtractive steps such as etching and additive steps such as sputtering or vacuum deposition. Any other steps known in the lithographic arts may be used to continue processing the material supported by the substrate to form an integrated circuit, device, or the like. Again, if one or more nanostructures is formed, suitable steps may be taken to locate, store, and protect the resulting nanostructures. Once the step 790 has been completed, the method 700 may end 798.

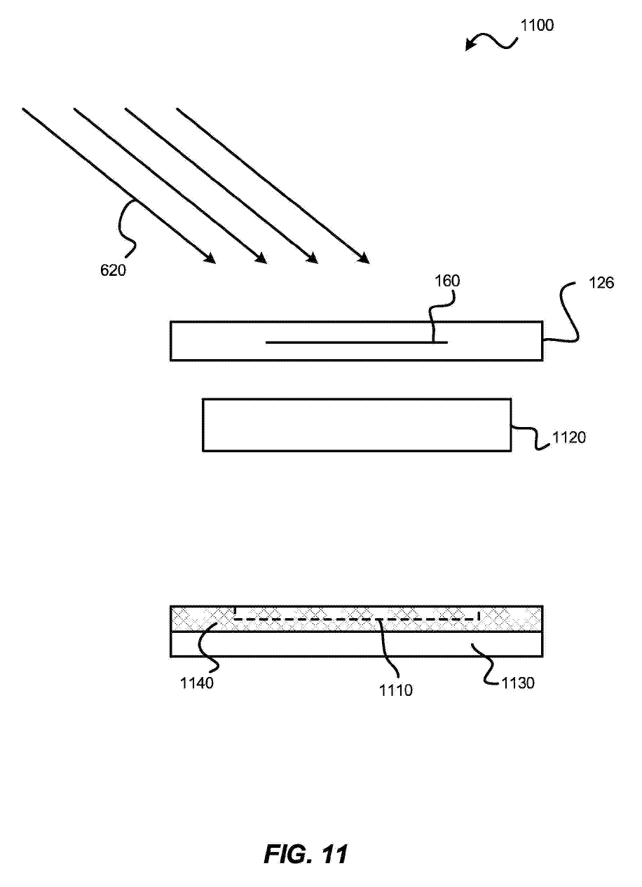

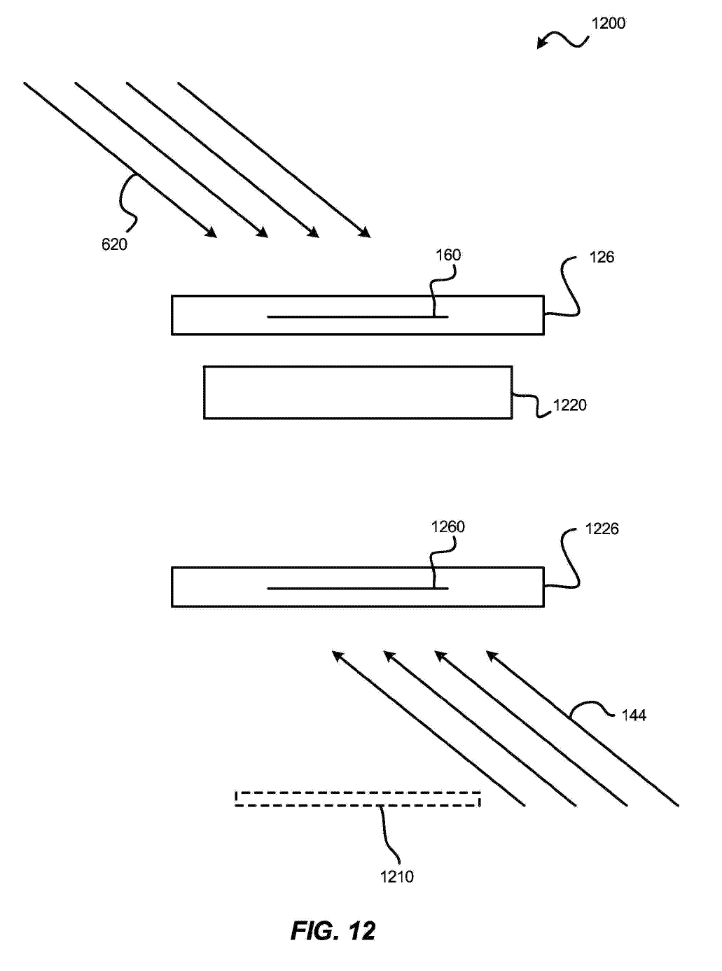

As mentioned previously, holography may be used according to the present invention to facilitate a wide variety of manufacturing processes. FIGS. 8-10 illustrate some potential ways to arrange system components (for example, in the step 720 or the step 760) to carry out hologram-assisted 3D printing. FIGS. 11 and 12 illustrate some potential ways to arrange system components (for example, in the step 720 or the step 760) to carry out hologram-assisted lithographic processing.

Referring to FIG. 8, a schematic view illustrates a holographic imaging system, or system 800, as applied to 3D printing according to one embodiment of the invention. The system 800 may include the coherent light source 120 or a non-coherent light source of the required wavelength (not shown in FIG. 8), the hologram, and a reservoir 810 containing photosensitive material 820. The hologram may be an Hi master hologram, and may thus include the hologram 160 recorded on the holographic recording medium 126. Alternatively, the hologram may be an H2 hologram, an H3 hologram, or other hologram formed from an H1 master hologram through the use of additional steps as set forth previously. The photosensitive material 820 may be in liquid, gaseous, solid, or amorphous form. In some embodiments, the photosensitive material 820 is in a liquid or gel form and is made to solidify in response to impingement of the light of the holographic image.

FIG. 8 may represent the manner in which the components are arranged in the step 760 if no image reduction is desired. Thus, the reservoir 810 may be positioned, relative to the hologram, such that the holographic image 610 is projected directly (i.e., without reduction) into the photosensitive material 820 within the reservoir 810. The holographic image 610 may cause a quantity of the photosensitive material 820 to solidify into the shape of the item 110. The resulting new object may be substantially the same size as the item 110.

The hologram 160 may be the original hologram recorded directly from the item 110, as illustrated in FIG. 1. Thus, the system 800 may represent the arrangement of the components in the step 760 if the step 720, the step 730, the step 740, and the step 750 of the method 700 of FIG. 7 have been omitted, and no further image reduction is desired. In alternative embodiments, the step 720, the step 730, the step 740, and the step 750 may be performed as described in connection with FIG. 7, and then in the step 760, the components may be positioned substantially as shown in FIG. 8, except that in place of the hologram 160 recorded directly from the item 110 (i.e., the H1 master hologram), the hologram with the reduced image (the H2 hologram or another derivative hologram) may be used.

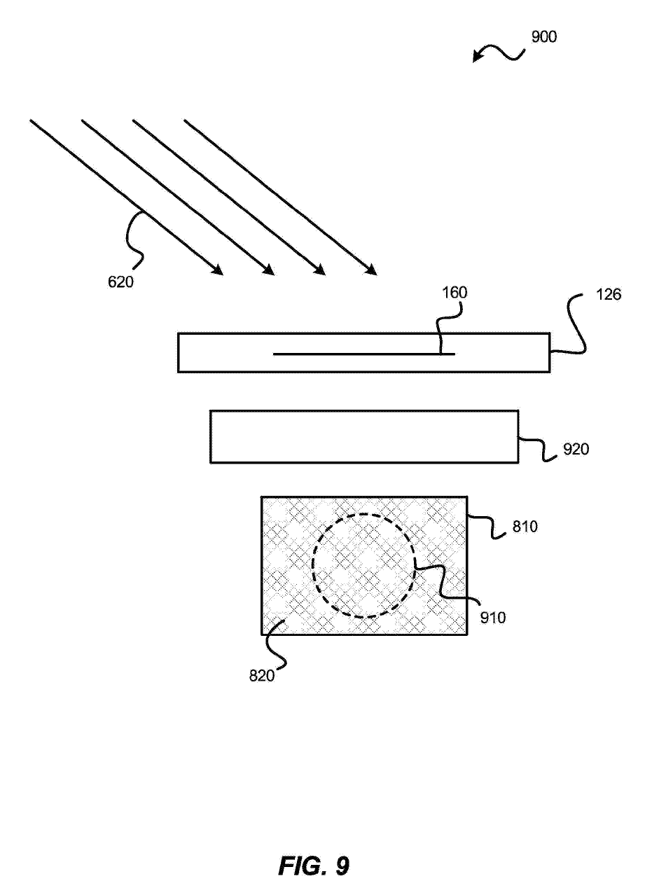

In order to scale the new object relative to the hologram 160 (or alternatively, the already scaled hologram used in place of the H1 master hologram), image reduction optics (or image expansion optics) may be added. One example of this will be shown and described in connection with FIG. 9.

Referring to FIG. 9, a schematic view illustrates a holographic imaging system, or system 900, as applied to 3D printing according to another embodiment of the invention. As shown, the system 900 may be used to provide a holographic image 910 that is scaled relative to the hologram 160. FIG. 9 may provide image reduction so that the holographic image 910 is relatively smaller than the hologram 160. This may be achieved by projecting the holographic image 910 through image reduction optics 920, which may include mirrors, lenses, and/or other features that optically reduce the size of the holographic image 910 relative to that of the hologram 160.

Depending on the degree of image reduction used, the holographic image 910 may even be one or more orders of magnitude smaller than the item 110 and/or the hologram 160. If desired, the system 900 may be used to create microstructures and/or nanostructures. Notably, the present invention may be used to create microstructures and/or nanostructures, not just singly, but also in arrays. In the alternative, if desired, the image reduction optics 920 may be replaced with image enlargement optics so that the holographic image 910 is larger than the hologram 160 and/or the item 110.

If the holographic image 910 is projected from the hologram 160 formed directly from the item 110, as illustrated in FIG. 9, the system 900 may represent the arrangement of the components in the step 760 if the step 720, the step 730, the step 740, and the step 750 are omitted. As with the previous embodiment, a hologram such as an H2 hologram or another derivative hologram on which a reduced image of the item 110 has been recorded may be substituted for the H1 master hologram if further reduction is desired.

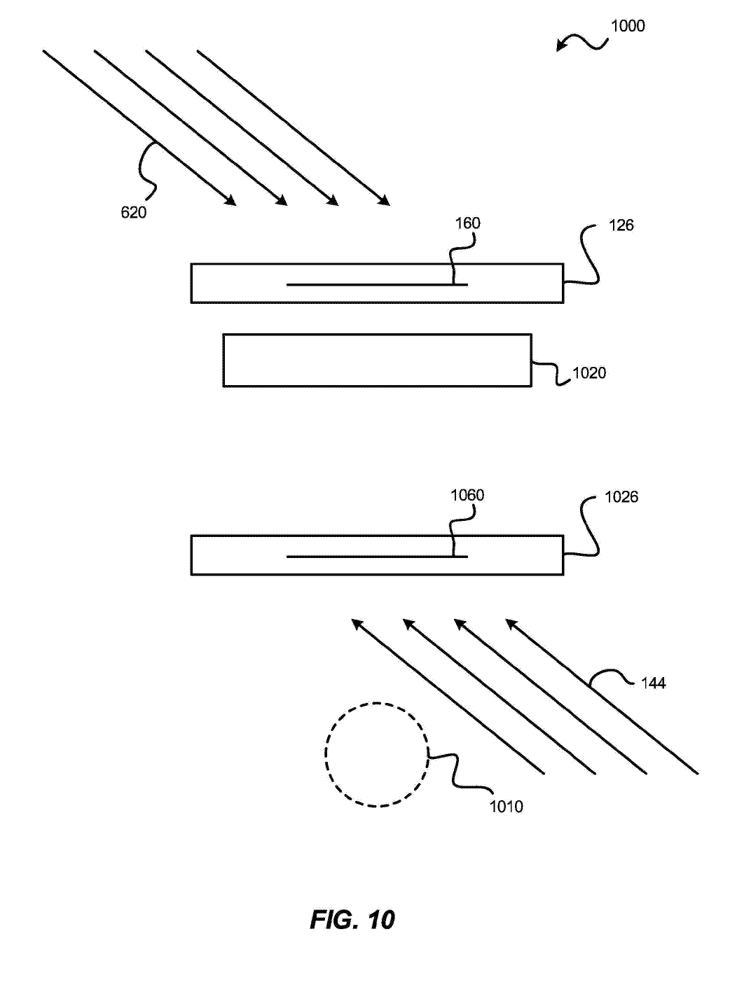

Referring to FIG. 10, a schematic view illustrates a holographic imaging system for creating an imaged reduced H2 hologram, or system 1000, as applied to 3D printing according to another embodiment of the invention. As shown, the system 1000 may also record a hologram that is smaller than the item 110. However, in FIG. 10, this may be done by recording a reduced hologram 1060 on a second holographic recording medium 1026, as in step 720, step 730, step 740, and step 750 of FIG. 7.

More specifically, image reduction optics 1020 may be positioned between the H1 master hologram and the second holographic recording medium 1026. The second holographic recording medium 1026 may be positioned at the desired location with respect to where the holographic image 610 would ordinarily be projected relative to the H1 master hologram. Thus, the beam 620 may illuminate the H1 master hologram to cause projection of the holographic image 610 through the image reduction optics 1020, which may result in recordation of the reduced hologram 1060 on the second holographic recording medium 1026 to provide an H2 hologram.

In order to form the H2 hologram, a reference beam 144 may be projected on the second holographic recording medium 1026. The holographic image 610 from the H1 master hologram may act as the object beam. The object beam and the reference beam 144 may cooperate to define an interference pattern at the second holographic recording medium 1026. After processing, the reduced hologram 1060 on the second holographic recording medium 1026 may be used as the H2 hologram.

The H2 hologram may subsequently be used to project a holographic image 1010 smaller than the H1 master hologram. The holographic image 1010 may be used for 3D printing, for example, by positioning the holographic image 1010 within a photosensitive material, such as the reservoir 810 of photosensitive material 820 as in FIG. 8 or FIG. 9. The holographic image 1010 may be projected into the photosensitive material 820 as shown and described in connection with the holographic image 610 of FIGS. 8 and 9. The resulting 3D object may be made without further reduction as in FIG. 8, or with further reduction through the use of image reduction optics 920 as in FIG. 9.

As mentioned previously, the reduction process embodied in FIG. 10 may not be diffraction limited since the holographic image that forms the hologram 160 may, itself, be formed by diffraction. Thus, a high level of reduction may be obtained with a single iteration. However, if desired, multiple iterations may be performed, for example, by projecting the holographic image 1010 from the H2 hologram through image reduction optics to record a further reduced hologram on a third holographic recording medium (not shown). After processing, this further reduced hologram may be used as an H3 hologram.

The systems and methods of the present invention may offer several advantages, as applied to 3D printing. For example, an entire object may be printed at once and/or made layer by layer. Further, smaller object sizes can be achieved due to the fact that diffraction limitations may not limit the reduction of the holographic image. Yet further, with particular reference to the system 1000 of FIG. 10, reduction of the holographic image 1010 may be obtained through reduction of the diffracted holographic image as a light source, rather than reduction of the physical image; this may further allow for the formation of smaller objects.

Referring to FIG. 11, a schematic view illustrates a holographic imaging system, or system 1100, as applied to lithography according to one embodiment of the invention. The system 1100 may include the coherent light source 120 or a non-coherent light source (not shown in FIG. 11), the holographic recording medium 126, and a substrate 1130 on which a layer of photosensitive material 1140 is positioned. The holographic recording medium 126 may have the hologram 160 recorded thereon as an H1 master hologram. In alternative embodiments, the hologram 160 may be an H2 hologram, an H3 hologram, or a subsequent derivative hologram. The photosensitive material 1140 may be in liquid, gaseous, solid, or amorphous form. In some embodiments, the photosensitive material 1140 is in a solid or gel form.

The item 110 used to record the hologram 160 may be a lithographic pattern or the like, and may exist in two or three dimensions. The substrate 1130 and adhering structures may be used to form integrated circuits. If desired, the system 1100 of FIG. 11 may be used to imprint an integrated circuit pattern on the substrate 1130. Thus, the item 110 used to form the hologram 160 may more specifically be an integrated circuit design, an inverse of an integrated circuit design that defines regions between integrated circuit components, or the like.

FIG. 11 may represent the manner in which the components are arranged in the step 760 of FIG. 7 if image reduction is desired between the holographic recording medium 126 and the photosensitive material 1140. Thus, the substrate 1130 and the photosensitive material 1140 may be positioned, relative to the H1 master hologram, such that a holographic image 1110 is projected through image reduction optics 1120 onto the photosensitive material 1140. The image reduction optics 1120 may include mirrors, lenses, and/or other features that optically reduce the size of the holographic image 1110 relative to that of the hologram 160.

The holographic image 1110 may cause a quantity of the photosensitive material 1140 to become solid, more easily removed, or more resistant to removal as described above. The pattern defined by the holographic image 1110 may match the lithographic pattern of the item 110. Thus, the holographic image 1110 may define an integrated circuit or the like.

The hologram 160 may be the original hologram recorded directly from the item 110 (i.e., the H1 master hologram), as illustrated in FIG. 1. Thus, the system 1100 may represent the arrangement of the components in the step 760 if the step 720, the step 730, the step 740, and the step 750 of the method 700 of FIG. 7 have been omitted, and no further image reduction is desired. In alternative embodiments, the step 720, the step 730, the step 740, and the step 750 may be performed as described in connection with FIG. 7, and then in the step 760, the components may be positioned substantially as shown in FIG. 8, except that in place of the holographic recording medium 126 with the hologram 160 recorded directly from the item 110, the holographic recording medium with the reduced image (the H2 hologram, H3 hologram, or subsequent derivative hologram) may be used.

Depending on the degree of image reduction used, the holographic image 1110 may even be one or more orders of magnitude smaller than the item 110 and/or the hologram 160. If desired, the system 1100 may be used to create microstructures and/or nanostructures. Notably, the present invention may be used to create microstructures and/or nanostructures, not just singly, but also in arrays. In the alternative, if desired, the image reduction optics 1120 may be replaced with image enlargement optics so that the holographic image 1110 is larger than the hologram 160 and/or the item 110.

Referring to FIG. 12, a schematic view illustrates a holographic imaging system for creating an image reduced H2 hologram, or system 1200, as applied to lithography according to another embodiment of the invention. As shown, the system 1200 may also produce a holographic image 1210 that is smaller than the item 110. However, in FIG. 12, this may be done by recording a reduced hologram 1260 on a second holographic recording medium 1226, as in step 720, step 730, step 740, and step 750 of FIG. 7.

More specifically, image reduction optics 1220 may be positioned between the H1 master hologram and the second holographic recording medium 1226. The second holographic recording medium 1226 may be positioned at the location with respect to where the holographic image 610 would ordinarily be projected relative to the H1 master hologram. Thus, the beam 620 may illuminate the H1 master hologram to cause projection of the holographic image 610 through the image reduction optics 1220, which may result in recordation of the reduced hologram 1260 on the second holographic recording medium 1226 to provide an H2 hologram.

In order to form the H2 hologram, a reference beam 144 may be projected on the second holographic recording medium 1226. The holographic image 610 from the H1 master hologram may act as the object beam. The object beam and the reference beam 144 may cooperate to define an interference pattern at the second holographic recording medium 1226. After processing, the reduced hologram 1260 on the second holographic recording medium 1226 may become the H2 hologram.

The H2 hologram may subsequently be used to project a holographic image 1210 smaller than the Hi master hologram. The holographic image 1210 may be used for lithography, for example, by positioning the holographic image 1210 within a photosensitive material, such as the photosensitive material 1140 on the substrate 1130 as in FIG. 11. The holographic image 1210 may be projected into the photosensitive material 1140 as shown and described in connection with the holographic image 1110 of FIG. 11. The resulting lithographic pattern may be made without further reduction, or with further reduction through the use of image reduction optics 1120 as in FIG. 11.

As mentioned previously, the reduction process embodied in FIG. 12 may not be diffraction limited since the holographic image that forms the reduced hologram 1260 may, itself, be formed by diffraction. Thus, a high level of reduction may be obtained with a single iteration. However, if desired, multiple iterations may be performed, for example, by projecting a holographic image 1210 from the H2 hologram through image reduction optics to record a further reduced hologram on a third holographic recording medium (not shown). After processing, this further reduced image may become an H3 hologram.

The systems and methods of the present invention may offer several advantages, as applied to lithography. For example, an entire wafer may be printed at once, i.e., in a single exposure. Further, smaller object sizes can be achieved due to the fact that diffraction limitations may not limit the reduction of the holographic image. Yet further, with particular reference to the system 1200 of FIG. 12, reduction of the holographic image 1210 may be obtained through reduction of the diffracted holographic image as a light source, rather than reduction of the physical image; this may further allow for the formation of smaller objects. Hence, small structures such as nanostructures may be lithographically printed. In contrast to known interference lithography techniques, the present invention may permit non-periodic patterns to be lithographically printed.

What is claimed is:

1. A system comprising:
a substrate that supports a photosensitive material;
a hologram on which a lithographic pattern is recorded, wherein the hologram is positioned relative to the substrate;
a light source tuned to the photosensitive material such that, in response to impingement of light from the light source on the hologram, a holographic image of the lithographic pattern is projected onto the photosensitive material.

2. The system of claim 1, wherein the lithographic pattern comprises a selection from the group consisting of an integrated circuit design and an inverse of an integrated circuit design, wherein the inverse of the integrated circuit design defines regions between integrated circuit components.

3. The system of claim 1, further comprising image reduction optics positionable proximate the hologram and the substrate such that the holographic image is reduced and is smaller than the lithographic pattern.

4. The system of claim 3, wherein the holographic image defines a nanostructure comprising a largest dimension that is less than 100 nm.

5. The system of claim 3, further comprising:
a preliminary hologram on which a preliminary lithographic pattern is recorded; and
preliminary image reduction optics positionable proximate the preliminary hologram and a holographic recording medium such that the hologram is recorded in the holographic recording medium in response to illumination of the preliminary hologram to project a preliminary holographic image of the preliminary lithographic pattern through the preliminary image reduction optics, and onto the holographic recording medium.

6. A method comprising:
using a light source to illuminate a hologram on which a lithographic pattern is recorded;
in response to illumination of the hologram, projecting a holographic image of the lithographic pattern onto a photosensitive material supported by a substrate; and
in response to projection of the holographic image onto the photosensitive material, performing a step selected from the group consisting of:
solidifying the photosensitive material underlying the holographic image;
facilitating removal of the photosensitive material underlying the holographic image; and
protecting the photosensitive material underlying the holographic image from removal.

7. The method of claim 6, wherein the lithographic pattern comprises a selection from the group consisting of an integrated circuit design and an inverse of an integrated circuit design, wherein the inverse of the integrated circuit design defines regions between integrated circuit components.

8. The method of claim 6, further comprising positioning image reduction optics proximate the hologram and the photosensitive material, wherein projecting the holographic image of the lithographic pattern onto the photosensitive material comprises projecting the holographic image through the image reduction optics such that the holographic image is smaller than the lithographic pattern.

9. The method of claim 8, wherein the holographic image defines a nanostructure comprising a largest dimension that is less than 100 nm.

10. The method of claim 8, further comprising, prior to illuminating the hologram:
illuminating a preliminary hologram on which a preliminary lithographic pattern is recorded;
in response to illumination of the preliminary hologram, projecting a preliminary holographic image of the preliminary lithographic pattern through preliminary image reduction optics and onto a holographic recording medium; and
in response to projection of the preliminary holographic image onto the holographic recording medium, recording the hologram in the holographic recording medium.

11. A method comprising:
dividing a first beam of light into a first object beam and a first reference beam;
illuminating a lithographic pattern with the first object beam;
illuminating a first holographic recording medium with the first reference beam;
reflecting a portion of the first object beam off of the lithographic pattern and onto the first holographic recording medium such that, at the first holographic recording medium, the first object beam and the first reference beam cooperate to define an interference pattern that records a first hologram in the first holographic recording medium;
after recording the first hologram, illuminating a selection from the group consisting of the first hologram and a second hologram recorded in response to projection of a first holographic image from the hologram on a second holographic recording medium;
in response to illumination of the selection, projecting a final holographic image of the lithographic pattern onto a photosensitive material supported by a substrate; and
in response to projection of the final holographic image onto the photosensitive material, performing a step selected from the group consisting of:
solidifying the photosensitive material underlying the final holographic image;
facilitating removal of the photosensitive material underlying the final holographic image; and
protecting the photosensitive material underlying the final holographic image from removal.

12. The method of claim 11, wherein the lithographic pattern comprises a selection from the group consisting of an integrated circuit design and an inverse of an integrated circuit design, wherein the inverse of the integrated circuit design defines regions between integrated circuit components.

13. The method of claim 11, wherein projecting the final holographic image of the lithographic pattern onto the photosensitive material comprises projecting the final holographic image through first image reduction optics such that the final holographic image is smaller than the lithographic pattern.

14. The method of claim 13, wherein the final holographic image defines a nanostructure comprising a largest dimension that is less than 100 nm.

15. The method of claim 13, wherein the selection comprises the second hologram, the method further comprising, after recording the first hologram and prior to illuminating the selection:
illuminating the first hologram;
in response to illumination of the first hologram, projecting the first holographic image on the second holographic recording medium through second image reduction optics; and
in response to projection of the first holographic image on the second holographic recording medium through the second image reduction optics, recording the second hologram in the second holographic recording medium such that the second hologram is smaller than the first hologram.
